(19) United States
(12) Patent Application Publication
(10) Pub. No.: US 2026/0150205 A1
(43) Pub. Date: May 28, 2026

(54) PRESSURE ADJUSTMENT COVER AND POWER CONTROL DEVICE INCLUDING SAME

(71) Applicants: HYUNDAI MOTOR COMPANY, SEOUL (KR); KIA CORPORATION, SEOUL (KR)

(72) Inventors: Ok Geun Ha, Hwaseong-si (KR); Byung Kwon Han, Hwaseong-si (KR); Hyong Joon Park, Hwaseong-si (KR); Seung Bae Jeong, Hwaseong-si (KR)

(73) Assignees: HYUNDAI MOTOR COMPANY, SEOUL (KR); KIA CORPORATION, SEOUL (KR)

(21) Appl. No.: 19/225,761

(22) Filed: Jun. 2, 2025

(30) Foreign Application Priority Data
Oct. 24, 2024 (KR) 10-2024-0146550

(51) Int. Cl. H05K 5/02; H02M 3/00; H05K 5/03; H05K 5/10

(52) U.S. Cl. CPC H05K 5/0212; H02M 3/003; H05K 5/03; H05K 5/10

(57) ABSTRACT

A power control device includes a housing formed of a non-conductive material and having an accommodating space, an inverter module located in the accommodating space, and a pressure adjustment cover coupled to the housing and separating the accommodating space from an external space, wherein the pressure adjustment cover includes an upper cover, a lower cover coupled to the upper cover, and a pressure adjustment member located between the upper cover and the lower cover, and a first elastic modulus of the lower cover is greater than a second elastic modulus of the pressure adjustment member.

### CROSS REFERENCE TO RELATED APPLICATIONS

This application claims benefit of priority to Korean Patent Application No. 10-2024-0146550 filed on Oct. 24, 2024 in the Korean Intellectual Property Office, the disclosure of which is incorporated herein by reference in its entirety.

### BACKGROUND

### 1. Field

The present disclosure relates to a pressure adjustment cover including a pressure adjustment member for controlling internal pressure, and a power control device including the same.

### 2. Description of Related Art

Eco-friendly vehicles using a motor as a driving source, such as hybrid vehicles or electric vehicles, may use a high-voltage battery as an energy source for driving the motor. Vehicles may use an inverter module providing power to the motor as a power conversion component and a low-voltage DC-DC converter (hereinafter referred to as LDC) generating power of about 12 V.

The inverter converts DC power of the high-voltage battery into three-phase AC power between the motor and the high-voltage battery and provides the three-phase AC power to the motor, and the LDC (or converter) may convert the voltage of the DC power of the high-voltage battery and provide the same to electrical components of the vehicle. Hereinafter, LDC may refer to a converter herein.

An inverter, a converter, and a controller for controlling the inverter and converter may be integrated into a package to form a power control device. The power control device may include a housing providing an interface for assembling internal components, such as an inverter and a converter, and protect the components.

The power control device may use separate equipment, such as a pressure regulator to regulate internal pressure. However, if separate equipment is used, additional equipment, such as a separate housing, may be required. In addition, internal condensation may occur due to air introduced through the separate equipment.

### SUMMARY

An aspect of the present disclosure is to provide a pressure adjustment cover and a power control device including the same providing a structure for controlling internal pressure of the power control device by including a member for controlling the internal pressure of the power control device, without an additional component.

According to an aspect of the present disclosure, a power control device includes a housing formed of a non-conductive material and having an accommodating space, an inverter module located in the accommodating space, and a pressure adjustment cover coupled to the housing and separating the accommodating space from an external space. The pressure adjustment cover includes an upper cover, a lower cover coupled to the upper cover, and a pressure adjustment member located between the upper cover and the lower cover, and a first elastic modulus of the lower cover is greater than a second elastic modulus of the pressure adjustment member.

The pressure adjustment cover may have a pressure adjustment space defined by the upper cover and the lower cover, and the pressure adjustment member may be located in the pressure adjustment space.

The upper cover may have a pressure adjustment hole connecting the pressure adjustment space to the accommodating space.

The pressure adjustment member may include rubber or iron.

A first distance from a lower surface of the lower cover to an upper surface of the pressure adjustment member may be greater than a second distance from the lower surface of the lower cover to a lower surface of the upper cover.

A thickness of the pressure adjustment member may be greater than a thickness of the upper cover.

The upper cover may have a through-hole penetrating through the upper cover, and the pressure adjustment member may be exposed to the accommodating space through the through-hole.

The upper cover may include an upper cover body, and an upper adjustment member connected to the upper cover body and having a third elastic modulus. The upper adjustment member is located on the pressure adjustment member, and the third elastic modulus is lower than the first elastic modulus.

The third elastic modulus may be lower than the second elastic modulus.

The upper adjustment member may have a shape convex toward the accommodating space.

According to another aspect of the present disclosure, a pressure adjustment cover may include an upper cover, a lower cover coupled to the upper cover, and a pressure adjustment member located between the upper cover and the lower cover. A first elastic modulus of the lower cover is greater than a second elastic modulus of the pressure adjustment member.

The upper cover may include an upper cover body, and an upper adjustment member connected to the upper cover and having a third elastic modulus.

The third elastic modulus may be the same as the first elastic modulus.

The third elastic modulus may be greater than the second elastic modulus.

The upper adjustment member may have a pressure adjustment hole, and the pressure adjustment member may be exposed externally through the pressure adjustment hole.

A thickness of the pressure adjustment member may be greater than a thickness of the lower cover.

### BRIEF DESCRIPTION OF THE FIGURES

The above and other aspects, features, and advantages of the present disclosure will be more clearly understood from the following detailed description, taken in conjunction with the accompanying drawings, in which:

FIG. 1 is a perspective view illustrating a power control device according to an embodiment of the present disclosure;

FIG. 2 is an exploded perspective view illustrating a power control device according to an embodiment of the present disclosure;

FIG. 3 is an exploded perspective view illustrating a power control device according to an embodiment of the present disclosure;

FIG. 4 is a perspective view illustrating a pressure adjustment cover according to an embodiment of the present disclosure;

FIG. 5 is an exploded perspective view illustrating a pressure adjustment cover according to an embodiment of the present disclosure;

FIG. 6 is a cross-sectional view illustrating a pressure adjustment cover according to an embodiment of the present disclosure;

FIG. 7 is a cross-sectional view illustrating a portion of a pressure adjustment cover according to an embodiment of the present disclosure;

FIG. 8 is a cross-sectional view illustrating a portion of a pressure adjustment cover according to an embodiment of the present disclosure;

FIG. 9 is a cross-sectional view illustrating a portion of a pressure adjustment cover according to an embodiment of the present disclosure;

FIG. 10 is a perspective view illustrating a pressure adjustment cover according to an embodiment of the present disclosure; and

FIG. 11 is a perspective view illustrating a pressure adjustment cover according to an embodiment of the present disclosure.

### DETAILED DESCRIPTION

While the present disclosure may be modified in various ways and take on various alternative forms, specific embodiments thereof are shown in the drawings and described in detail below. However, it should be understood that there is no intent to limit the present disclosure to the particular forms disclosed, but on the contrary, the present disclosure covers all modifications, equivalents, and alternatives falling within the spirit and scope of the present disclosure.

It will be understood that, although the terms “first,” “second,” etc. may be used herein to describe various elements, these elements should not be limited by these terms. These terms are only used to distinguish one element from another. For example, a first element could be termed a second element, and a second element could similarly be termed a first element without departing from the scope of the present disclosure. As used herein, the term “and/or” includes any and all combinations of one or more of the associated listed items.

The terms, such as “unit, part, portion, etc.” may be used to describe various components, but the components should not be limited by these terms. The above terms may refer to not only physically/visually distinct components, but also to functions or components of a portion even if the corresponding portion is not clearly divided.

The terms used herein to describe embodiments of the present disclosure is not intended to limit the scope of the present disclosure. The articles “a,” and “an” are singular in that they have a single referent, however the use of the singular form in the present document should not preclude the presence of more than one referent. In other words, elements of the present disclosure referred to in the singular may number one or more, unless the context clearly indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein including technical and scientific terms have the same meanings as understood by those skilled in the art to which the present disclosure pertains. Such terms as defined in generally used dictionaries should be construed to have the same meanings as those of the contexts of the related art, and unless clearly defined in the application, they should not be construed to have ideally or excessively formal meanings.

In the description below, the terms “anterior,” “posterior,” “lateral,” “front,” “rear,” “up/down,” “above,” “upper,” “top,” “below” “lower” “bottom” “left/right” and the like are defined based on a vehicle or vehicle body. In addition, terms, such as first and second may be used to describe various components, but these components are not limited in order, size, location, or importance by terms, such as first and second and named for the sole purpose of distinguishing one component from another.

Hereinafter, embodiments of the present disclosure will be described with reference to the accompanying drawings.

In the drawings, D1 may be referred to as a first direction, D2 intersecting the first direction D1 may be referred to as a second direction, and D3 intersecting each of the first direction D1 and the second direction D2 may be referred to as a third direction. The first direction D1 may be referred to as an upward direction, and the direction opposite to the first direction D1 may be referred to as a downward direction. In addition, each of the second direction D2 and the third direction D3 may be referred to as a horizontal direction.

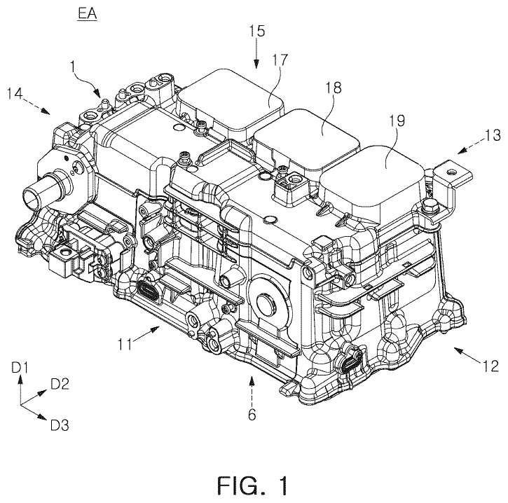

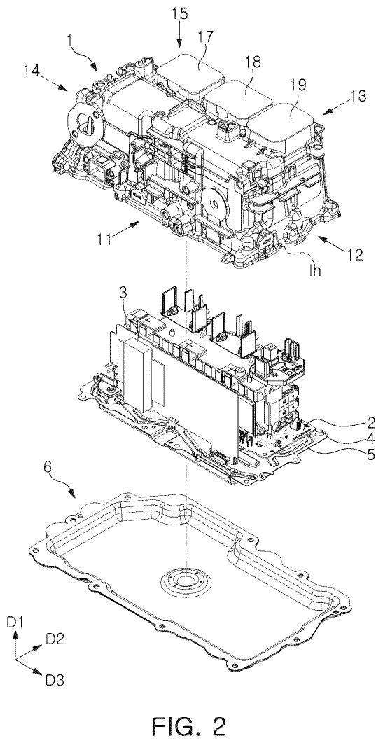

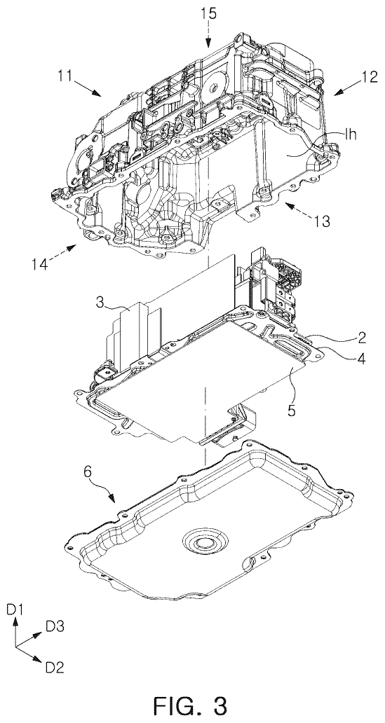

FIG. 1 is a perspective view illustrating a power control device EA according to an embodiment of the present disclosure, FIG. 2 is an exploded perspective view illustrating the power control device EA according to an embodiment of the present disclosure, and FIG. 3 is an exploded perspective view illustrating the power control device EA according to an embodiment of the present disclosure.

Referring to FIGS. 1, 2, and 3, the power control device EA according to an embodiment may include a housing 1, an inverter module 3, and a pressure adjustment cover 6. The power control device according to an embodiment may selectively include some of an LDC 2, a gate board 4, and a control board 5.

The housing 1 may accommodate various components of the power control device EA therein. The housing 1 may have an accommodating space 1h to accommodate various components of the power control device EA. The housing 1 may have a box shape with an open bottom.

The inverter module 3, the LDC 2, the gate board 4, and the control board 5 may be located in the accommodating space 1h. The inverter module 3, the LDC 2, the gate board 4, and the control board 5 may be appropriately arranged to occupy a predetermined area in the accommodating space 1h. For example, the inverter module 3, the LDC 2, the gate board 4, and the control board 5 may be sequentially located from top to bottom in the accommodating space 1h, but the arrangement relationship is not limited thereto.

The housing 1 may include a plurality of sidewalls 11, 12, 13, and 14 extending in a height direction along the open bottom edge. The housing 1 may include an upper surface 15 connected to the plurality of sidewalls 11, 12, 13, and 14.

The plurality of sidewalls 11, 12, 13, and 14 may include a first sidewall 11, a second sidewall 12, a third sidewall 13, and a fourth sidewall 14. However, for convenience, the plurality of sidewalls 11, 12, 13, and 14 may be described as a single unit in this specification.

A first connection portion 17, a second connection portion 18, and a mounting portion 19 may be located on an upper surface 15 of the housing 1.

A high-voltage current from a battery may be supplied to a device inside the housing 1 by the first connection portion 17. A high-voltage current may be discharged from the power control device EA to a motor by the second connection portion 18. The housing 1 and a junction box may be connected by the mounting portion 19.

The junction box may be installed at a location in which several wires are connected in an electrical system. The junction box may be used for branching, connecting, and protecting electrical wiring.

However, the arrangement relationship of the first connection portion 17, the second connection portion 18, and the mounting portion 19 is not limited to the aforementioned example.

The pressure adjustment cover 6 may be coupled to the housing 1. The pressure adjustment cover 6 according to an embodiment may be coupled to a lower surface of the housing 1. The pressure adjustment cover 6 may separate the accommodating space 1h from an external space. The accommodating space 1h and other components of the power control device EA located in the accommodating space 1h may be protected by the combination of the pressure adjustment cover 6 and the housing 1. The pressure adjustment cover 6 may support various configurations of the accommodating space 1h.

The pressure adjustment cover 6 may have a plate shape but is not limited thereto. The configuration of the pressure adjustment cover 6 is described below.

The positions and coupling relationship of the pressure adjustment cover 6 and the housing 1 are not limited thereto. The pressure adjustment cover 6 may be coupled not only to the lower surface of the housing 1, but also to the sidewalls 11, 12, 13, and 14 and the upper surface 15. The level of the pressure adjustment cover 6 may be higher than the level of the inverter module 3.

The inverter module 3 may convert direct current (DC) power into alternating current (AC) power. The inverter module 3 may convert power supplied from a battery into power that may be supplied to the motor.

The LDC 2 may convert a DC voltage into another DC voltage. The LDC 2 may be used to provide various voltage levels in an electronic device. More specifically, the LDC 2 may generate an output voltage lower than an input voltage. The LDC 2 may be used when a battery voltage is high and various devices have different voltage requirements. Power may be efficiently converted by the LDC 2, and energy loss may be reduced.

The gate board 4 may control and manage a signal of a semiconductor device. The semiconductor device may perform power conversion through a switching operation. The gate board 4 may control the operation of the semiconductor device by transmitting a switching signal. The gate board 4 may control a switching speed, voltage, and current characteristics to increase the power conversion efficiency.

The gate board 4 may include a driver circuit, a protection circuit, and an interface circuit. The driver circuit may amplify the control signal to supply the power required for the semiconductor device. The protection circuit may protect the device in situations, such as overcurrent, overvoltage, and overheating. The interface circuit may be in charge of communication between the gate board and the control board.

The control board 5 may collect data from various sensors and input devices. The control board 5 may control other components of the power control device EA. For example, the control board 5 may monitor an input voltage, output voltage, current, and temperature of the inverter module 3. The control board 5 may collect data through monitoring to optimize a power conversion process. The control board 5 may diagnose the status of the power control device EA and provide a warning when an abnormal situation occurs.

The control board 5 may include a microcontroller, a digital signal processor (DSP), and a memory, etc. The microcontroller and the DSP may be a central processing unit executing data processing and control algorithms. The memory may store and manage data.

However, the configuration of the power control device EA is not limited thereto. The power control device EA may further include other components that may supply power to the electronic components or control power.

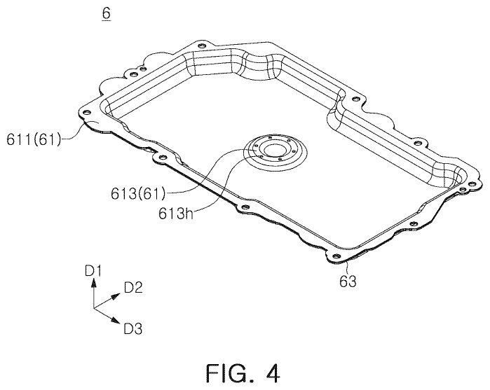

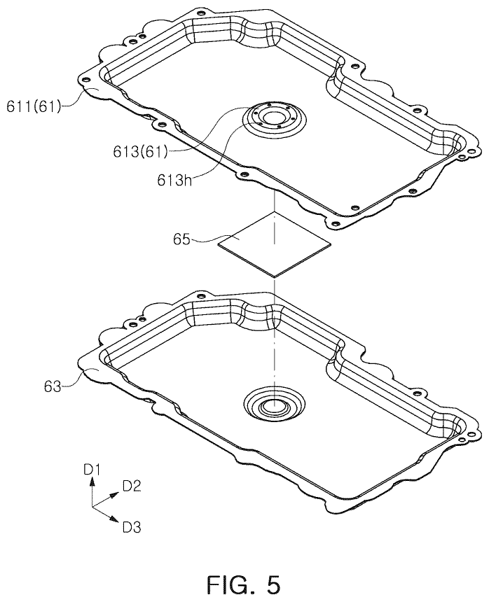

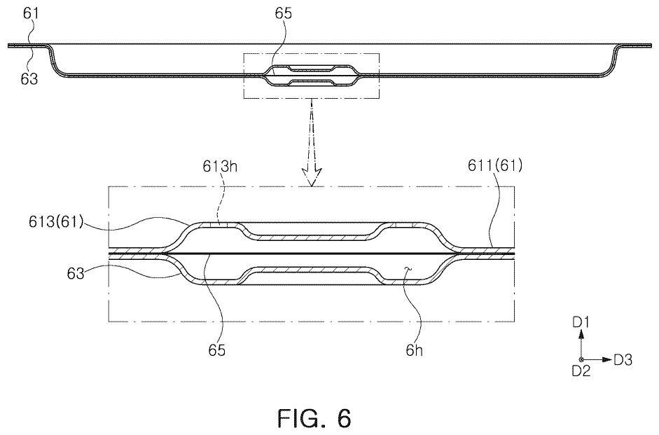

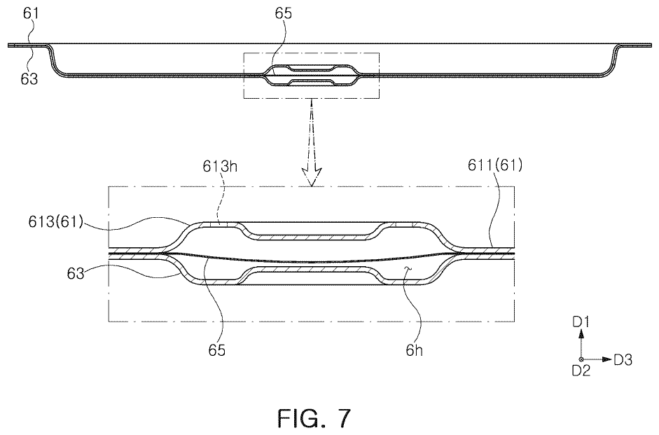

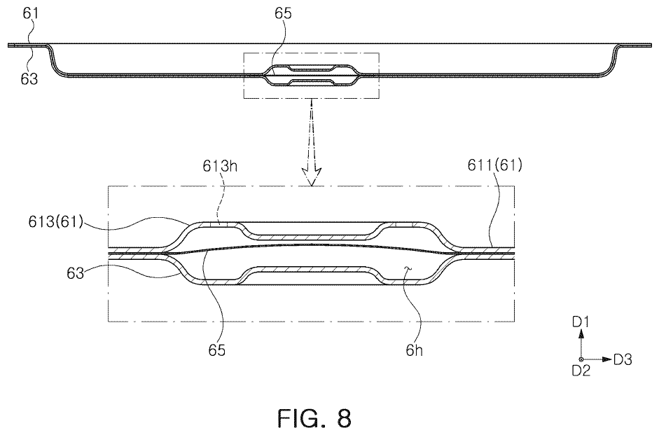

FIG. 4 is a perspective view illustrating the pressure adjustment cover 6 according to an embodiment of the present disclosure, FIG. 5 is an exploded perspective view illustrating the pressure adjustment cover 6 according to an embodiment of the present disclosure, FIG. 6 is a cross-sectional view illustrating the pressure adjustment cover 6 according to an embodiment of the present disclosure, FIG. 7 is a cross-sectional view illustrating the pressure adjustment cover 6 according to an embodiment of the present disclosure, and FIG. 8 is a cross-sectional view illustrating the pressure adjustment cover 6 according to an embodiment of the present disclosure.

Referring to FIGS. 4, 5, and 6, the pressure adjustment cover 6 may include an upper cover 61, a lower cover 63, and a pressure adjustment member 65.

The upper cover 61 may define a lower surface of the accommodating space 1h. The upper cover 61 may include a plurality of fastening holes to be coupled to the housing 1.

The upper cover 61 may include an upper cover body 611 and an upper adjustment member 613. The upper cover body 611 may have a plurality of fastening holes.

The upper adjustment member 613 may have a shape protruding convexly from the upper cover body 611 toward the accommodating space 1h. The upper adjustment member 613 may extend from the upper cover body 611 in the first direction D1. The upper adjustment member 613 may include the same material as that of the upper cover body 611. However, the shape and material of the upper adjustment member 613 are not limited thereto. This will be described below.

The lower cover 63 may be located below the upper cover 61. The position of the lower cover 63 may be lower than the position of the upper cover 61. The lower cover 63 may be coupled to the upper cover 61. The pressure adjustment cover 6 may have a pressure adjustment space 6h located between the upper cover 61 and the lower cover 63. The pressure adjustment space 6h may be defined by the upper cover 61 and the lower cover 63.

The upper adjustment member 613 may have a pressure adjustment hole 613h. The accommodating space 1h and the pressure adjustment space 6h may be connected by the pressure adjustment hole 613h. When the pressure of the accommodating space 1h changes, the pressure of the pressure adjustment space 6h may also change.

The pressure adjustment member 65 may adjust the pressure of the accommodating space 1h. The method for the pressure adjustment member 65 to adjust the pressure of the accommodating space 1h will be described below. The pressure adjustment member 65 may be located in the pressure adjustment space 6h. The pressure adjustment member 65 may be located between the upper cover 61 and the lower cover 63. The pressure adjustment member 65 may be exposed to the accommodating space 1h by the pressure adjustment hole 613h. The pressure adjustment member 65 may be exposed externally by the pressure adjustment hole 613h.

The lower cover 63, the upper cover 61, and the pressure adjustment member 65 may have elasticity. The lower cover 63, the upper cover 61, and the pressure adjustment member 65 may each have an elastic modulus. The elastic modulus may refer to the degree of resistance to force when force is applied to a material. For example, in a state in which external force is applied to the lower cover 63, the elastic modulus of the lower cover 63 may be smaller as the lower cover is deformed more. In a state in which external force is applied to the lower cover 63, the elastic modulus of the lower cover 63 may be greater as the lower cover is deformed less.

The lower cover 63 may have a first elastic modulus. The pressure adjustment member 65 may have a second elastic modulus. The pressure adjustment member 65 may selectively include one of rubber and iron. However, the material of the pressure adjustment member 65 is not limited thereto. The pressure adjustment member 65 may further include another material having elasticity.

The material of the upper cover body 611 may be the same as that of the lower cover 63. More specifically, the elastic modulus of the upper cover body 611 may be the same as that of the lower cover 63. The upper cover body 611 may have a first elastic modulus. The upper adjustment member 613 may have a third elastic modulus. The upper adjustment member 613 may include the same material as that of the upper cover body 611. More specifically, the third elastic modulus may be the same as the first elastic modulus. However, the relationship between the third elastic modulus and the first elastic modulus is not limited thereto. The third elastic modulus and the first elastic modulus may be different from each other. This will be described in detail below.

Referring to FIGS. 4 and 5, the pressure adjustment cover 6 in which the upper adjustment member 613, the upper cover body 611, and the lower cover 63 all contain the same material may be provided. More specifically, the third elastic modulus and the first elastic modulus may be the same. However, the second elastic modulus may be lower than the first elastic modulus. The first elastic modulus may be greater than the second elastic modulus. In other words, the pressure adjustment member 65 may deform more easily than the upper cover 61 and the lower cover 63 at the same pressure.

When the second elastic modulus is lower than the first elastic modulus, the pressure adjustment member 65 may also change when the pressure of the accommodating space 1h changes. Referring to FIG. 7, when the pressure of the accommodating space 1h increases, the pressure adjustment member 65 may have a shape concave toward the lower cover 63. Referring to FIG. 8, when the pressure of the accommodating space 1h decreases, the pressure adjustment member 75 may have a shape convex toward the upper cover 61. As the pressure of the accommodating space 1h changes, the shape of the pressure adjustment member 65 also changes, thereby reducing a pressure change rate of the accommodating space 1h. Since the second elastic modulus is lower than the first elastic modulus, the pressure adjustment member 65 may adjust the pressure of the accommodating space 1h.

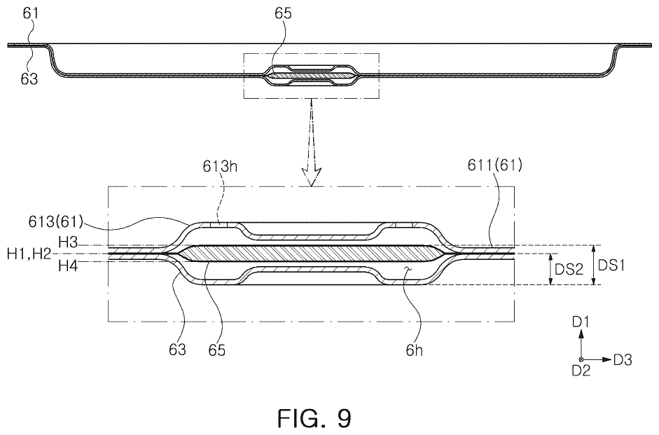

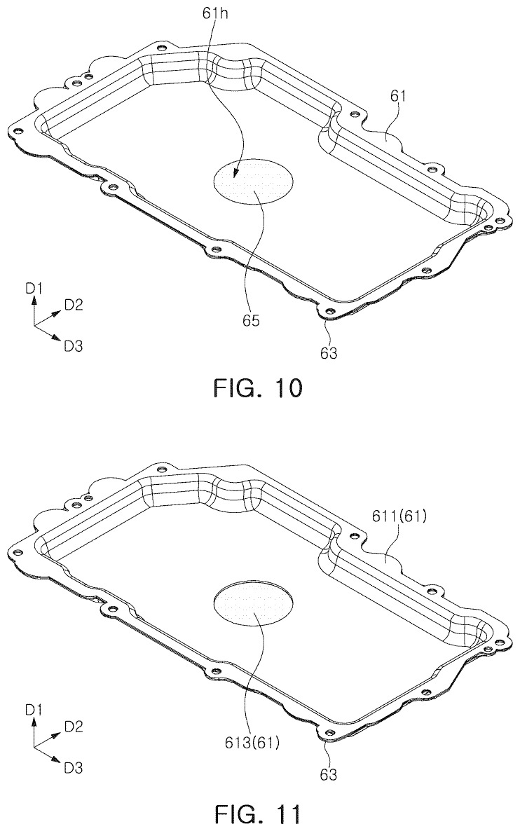

FIG. 9 is a cross-sectional view illustrating a portion of the pressure adjustment cover 6 according to an embodiment of the present disclosure, FIG. 10 is a perspective view illustrating the pressure adjustment cover 6 according to an embodiment of the present disclosure, and FIG. 11 is a perspective view illustrating the pressure adjustment cover 6 according to an embodiment of the present disclosure.

Referring to FIGS. 9, 10, and 11, the pressure adjustment covers 6 having various shapes may be provided.

Referring to FIG. 9, the pressure adjustment cover 6 according to an embodiment may include a thick pressure adjustment member 65. A position H3 of an upper surface of the pressure adjustment member 65 may be higher than a position H1 of a lower surface of the upper cover body 611. More specifically, a first distance DS1 from the lower surface of the lower cover 63 to the upper surface of the pressure adjustment member 65 may be greater than a second distance DS2 from the lower surface of the lower cover 63 to the lower surface of the upper cover 61. A position H4 of the lower surface of the pressure adjustment member 65 may be lower than a position H2 of the upper surface of the lower cover 63. A thickness of the pressure adjustment member 65 may be greater than a thickness of the upper cover 61. The thickness of the pressure adjustment member 65 may be greater than a thickness of the lower cover 63. However, the relationship among the pressure adjustment member 65, the upper cover 61, and the lower cover 63 is not limited thereto.

Referring to FIG. 10, the upper cover 61 according to an embodiment may have a through-hole 61h penetrating through the upper cover body 611. The upper cover 61 may not include the upper adjustment member. The pressure adjustment member may be exposed to the accommodating space by the through-hole 61h. When the upper cover 61 does not include the upper adjustment member 613, the pressure adjustment member 65 may react sensitively to a change in pressure in the accommodating space 1h.

Referring to FIG. 11, the upper cover 61 according to an embodiment may have the through-hole 61h penetrating through the upper cover body 611. The upper cover 61 may include a layer-shaped upper adjustment member 613 covering the through-hole 61h. The layer-shaped upper adjustment member 613 may be located on the pressure adjustment member 65. The third elastic modulus of the layer-shaped upper adjustment member 613 may be smaller than the second elastic modulus of the pressure adjustment member 65. The third elastic modulus may be lower than the first elastic modulus. However, the relationship among the third elastic modulus, the second elastic modulus, and the first elastic modulus is not limited thereto. The third elastic modulus may be greater than the second elastic modulus.

The pressure adjustment cover 6 illustrated in FIGS. 9, 10, and 11 is merely an example, and the shape and structure of the pressure adjustment cover 6 are not limited thereto. The shape and structure of the pressure adjustment cover 6 may be variously modified within a range in which the first elastic modulus of the lower cover 63 is greater than the second elastic modulus of the pressure adjustment member 65.

According to the power control device EA according to embodiments of the present disclosure, the degree of freedom in design may be increased by installing the pressure adjustment member 65 at various locations. The pressure adjustment cover 6 may be located in various locations of the power control device EA. The pressure adjustment cover 6 may be located not only on the lower surface of the power control device EA, but also on the sidewalls 11, 12, 13, and 14 or the upper surface 15 of the power control device EA. The pressure adjustment member 65 may be located in various locations as the location of the pressure adjustment cover 6 changes. In addition, the pressure adjustment member 65 may be located in any appropriate location within the pressure adjustment cover 6.

According to the power control device EA according to embodiments of the present disclosure, the manufacturing costs of the power control device EA may be reduced. By using the pressure adjustment member 65, the pressure of the accommodating space 1h may be controlled without a separate pressure adjustment device. Since a separate pressure adjustment device is not required, additional costs may not be incurred. Since a separate pressure adjustment device is not required and the structure is simple, it is possible to more easily prevent water vapor from flowing into the power control device EA. As the structure of the power control device EA is simplified, it is possible to prevent the addition of another structure for preventing water vapor from flowing into the accommodating space 1h.

The pressure adjustment cover according to an embodiment of the present disclosure and the power control device including the same may adjust the internal pressure of the power control device without an additional complicated configuration.

The pressure adjustment cover according to an embodiment of the present disclosure and the power control device including the same may prevent internal condensation from occurring by blocking air introduced into the power control device.

While embodiments have been shown and described above, it will be apparent to those skilled in the art that modifications and variations could be made without departing from the scope of the present disclosure as defined by the appended claims.

1. A power control device comprising:
a housing having an accommodating space;
an inverter module located in the accommodating space; and
a pressure adjustment cover coupled to the housing and separating the accommodating space from an external space;
wherein the pressure adjustment cover includes:
an upper cover;
a lower cover coupled to the upper cover; and
a pressure adjustment member located between the upper cover and the lower cover;
wherein a first elastic modulus of the lower cover is greater than a second elastic modulus of the pressure adjustment member.

2. The power control device of claim 1, wherein the pressure adjustment cover has a pressure adjustment space defined by the upper cover and the lower cover, and the pressure adjustment member is located in the pressure adjustment space.

3. The power control device of claim 2, wherein the upper cover has a pressure adjustment hole connecting the pressure adjustment space to the accommodating space.

4. The power control device of claim 1, wherein the pressure adjustment cover has a plate shape.

5. The power control device of claim 1, wherein the pressure adjustment member is made of rubber or iron.

6. The power control device of claim 1, wherein a first distance from a lower surface of the lower cover to an upper surface of the pressure adjustment member is greater than a second distance from the lower surface of the lower cover to a lower surface of the upper cover.

7. The power control device of claim 1, wherein a thickness of the pressure adjustment member is greater than a thickness of the upper cover.

8. The power control device of claim 1, wherein the upper cover has a through-hole penetrating through the upper cover, and the pressure adjustment member is exposed to the accommodating space through the through-hole.

9. The power control device of claim 1, wherein the upper cover includes:
an upper cover body; and
an upper adjustment member connected to the upper cover body and having a third elastic modulus;
wherein the upper adjustment member is located on the pressure adjustment member; and
wherein the third elastic modulus is less than the first elastic modulus.

10. The power control device of claim 9, wherein the third elastic modulus is less than the second elastic modulus.

11. The power control device of claim 9, wherein the upper adjustment member has a convex shape extending toward the accommodating space.

12. A pressure adjustment cover comprising:
an upper cover;
a lower cover coupled to the upper cover; and
a pressure adjustment member located between the upper cover and the lower cover;
wherein a first elastic modulus of the lower cover is greater than a second elastic modulus of the pressure adjustment member.

13. The pressure adjustment cover of claim 12, wherein the upper cover includes:
an upper cover body; and
an upper adjustment member connected to the upper cover and having a third elastic modulus.

14. The pressure adjustment cover of claim 13, wherein the third elastic modulus is equal to the first elastic modulus.

15. The pressure adjustment cover of claim 13, wherein the third elastic modulus is greater than the second elastic modulus.

16. The pressure adjustment cover of claim 13, wherein the upper adjustment member has a pressure adjustment hole, and the pressure adjustment member is exposed externally through the pressure adjustment hole.

17. The pressure adjustment cover of claim 16, wherein the upper adjustment member has a convex shape extending in a direction away from the lower cover.

18. The pressure adjustment cover of claim 12, wherein a thickness of the pressure adjustment member is greater than a thickness of the lower cover.

19. The pressure adjustment cover of claim 12, wherein the pressure adjustment cover has a pressure adjustment space defined by the upper cover and the lower cover, and the pressure adjustment member is located in the pressure adjustment space.

20. The pressure adjustment cover of claim 12, wherein the pressure adjustment member has a plate shape and is made of rubber or iron.
